(19) United States
(12) Patent Application Publication
(10) Pub. No.: US 2024/0147700 A1
(43) Pub. Date: May 2, 2024

(54) INTEGRATED CIRCUIT DEVICE

(71) Applicant: SAMSUNG ELECTRONICS CO., LTD., Suwon-si (KR)

(72) Inventor: Jongin KANG, Suwon-si (KR)

(21) Appl. No.: 18/381,744

(22) Filed: Oct. 19, 2023

(30) Foreign Application Priority Data
Nov. 1, 2022 (KR) 10-2022-0144017

(51) Int. Cl. H10B 12/00

(52) U.S. Cl. CPC H10B 12/34; H10B 12/053; H10B 12/315

(57) ABSTRACT

An integrated circuit device comprising a substrate having a first gate trench and a second gate trench apart from the first gate trench in a horizontal direction, a gate dielectric layer covering inner surfaces of the first gate trench and the second gate trench, a first lower gate line filling a portion of the first gate trench on the gate dielectric layer, a second lower gate line filling a portion of the second gate trench on the gate dielectric layer, a first upper gate line on the first lower gate line in the first gate trench and having a first width in the horizontal direction, a second upper gate line on the second lower gate line in the second gate trench and having a second width smaller than the first width.

### CROSS-REFERENCE TO RELATED APPLICATION

Korean Patent Application No. 10-2022-0144017, filed on Nov. 1, 2022, in the Korean Intellectual Property Office, is incorporated by reference herein in its entirety.

### BACKGROUND

### 1. Field

An integrated circuit device is disclosed.

### 2. Description of the Related Art

In accordance with the rapid development of the electronics industry and the needs of users, electronic devices have become more compact and lighter in weight.

### SUMMARY

An integrated circuit (IC) device may include a substrate having a first gate trench and a second gate trench apart from the first gate trench in a horizontal direction, a gate dielectric layer covering inner surfaces of the first gate trench and the second gate trench, a first lower gate line filling a portion of the first gate trench on the gate dielectric layer, and a second lower gate line filling a portion of the second gate trench on the gate dielectric layer. The integrated circuit device may include a first upper gate line on the first lower gate line in the first gate trench and having a first width in the horizontal direction, and a second upper gate line on the second lower gate line in the second gate trench and having a second width smaller than the first width. A vertical level of an upper surface of the first upper gate line may be higher than or substantially equal to a vertical level of an upper surface of the second upper gate line.

An IC device may include a substrate having a first gate trench and a second gate trench apart from the first gate trench in a horizontal direction, a gate dielectric layer covering inner surfaces of the first gate trench and the second gate trench, a first lower gate line filling a portion of the first gate trench on the gate dielectric layer, a second lower gate line filling a portion of the second gate trench on the gate dielectric layer, a first upper gate line on the first lower gate line in the first gate trench, and a second upper gate line on the second lower gate line in the second gate trench. A vertical level of an upper surface of the first upper gate line may be higher than or substantially equal to a vertical level of an upper surface of the second upper gate line, and the upper surfaces of the first upper gate line and the second upper gate line may have an upwardly convexly rounded profile.

An IC device may include a substrate including a first gate trench having a first width in a first horizontal direction and extending in a second horizontal direction orthogonal to the first horizontal direction and a second gate trench apart from the first gate trench in the first horizontal direction, having a depth deeper than a depth of the first gate trench in a vertical direction, and extending in the second horizontal direction. The IC device may include a gate dielectric layer covering inner surfaces of the first gate trench and the second gate trench, a first lower gate line filling a portion of the first gate trench on the gate dielectric layer, a second lower gate line filling a portion of the second gate trench on the gate dielectric layer, a first upper gate line on the first lower gate line in the first gate trench and having a first width in the horizontal direction, and a second upper gate line on the second lower gate line in the second gate trench and having a second width greater than the first width. A vertical level of an upper surface and a vertical level of a lower surface of the first upper gate line may be respectively higher than or substantially equal to a vertical level of an upper surface and a vertical level of a lower surface of the second upper gate line, the first upper gate line and the second upper gate line may include doped polysilicon, the first lower gate line and the second lower gate line may include Ti, TiN, Ta, TaN, W, WN, TiSiN, or WSiN, and upper surfaces of the first upper gate line and the second upper gate line may have an upwardly convexly rounded profile.

### BRIEF DESCRIPTION OF THE DRAWINGS

Features will become apparent to those of skill in the art by describing in detail exemplary embodiments with reference to the attached drawings in which:

FIG. 1 is a plan view of components of an integrated circuit (IC) device according to example embodiments.

FIG. 2A is a cross-sectional view of components, taken along lines X-X′ and Y-Y′ of FIG. 1, and FIGS. 2B and 2C are cross-sectional views of components of IC devices according to example embodiments.

FIG. 3A is a cross-sectional view of components, taken along lines X-X′ and Y-Y′ of FIG. 1 according to an example embodiment, and FIG. 3B is a cross-sectional view of components of an IC device.

FIG. 4A is a cross-sectional view of components, taken along lines X-X′ and Y-Y′ of FIG. 1 according to an example embodiment, and FIGS. 4B and 4C are cross-sectional views of components of IC devices according to example embodiments.

FIG. 5A is a cross-sectional view of components, taken along lines X-X′ and Y-Y′ of FIG. 1 according to an example embodiment, and FIGS. 5B and 5C are cross-sectional views of components of IC devices according to example embodiments.

FIGS. 6A to 6G are cross-sectional views of a method of manufacturing an IC device according to example embodiments.

FIG. 7 is a schematic plan layout view of components of an IC device according to example embodiments.

FIGS. 8A to 8I are cross-sectional views of a method of manufacturing an IC device according to example embodiments.

### DETAILED DESCRIPTION

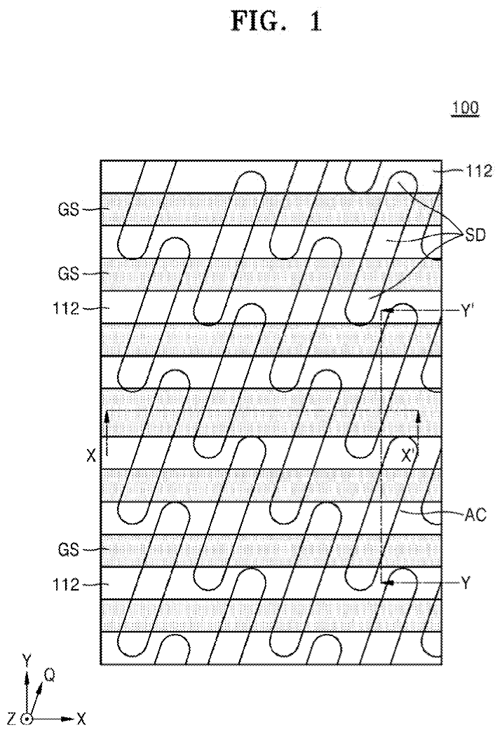

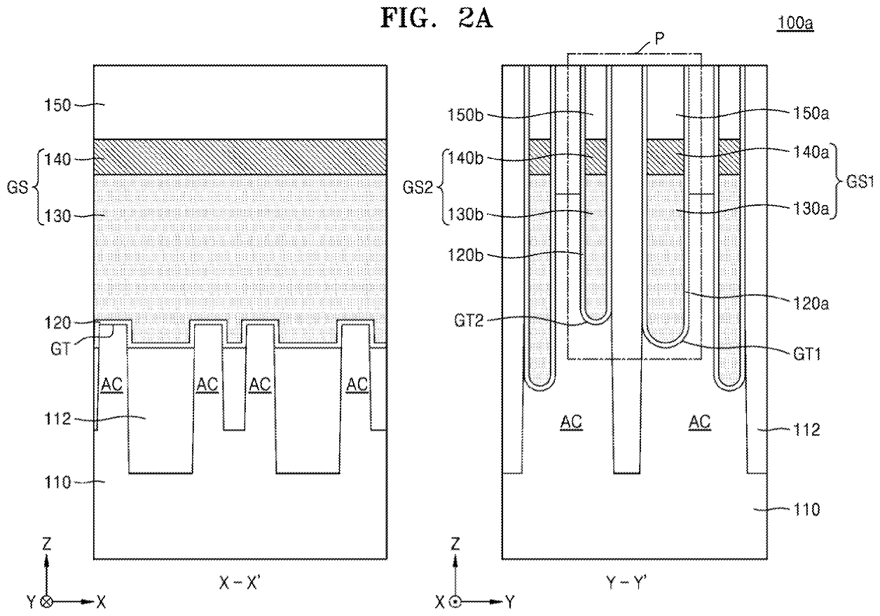

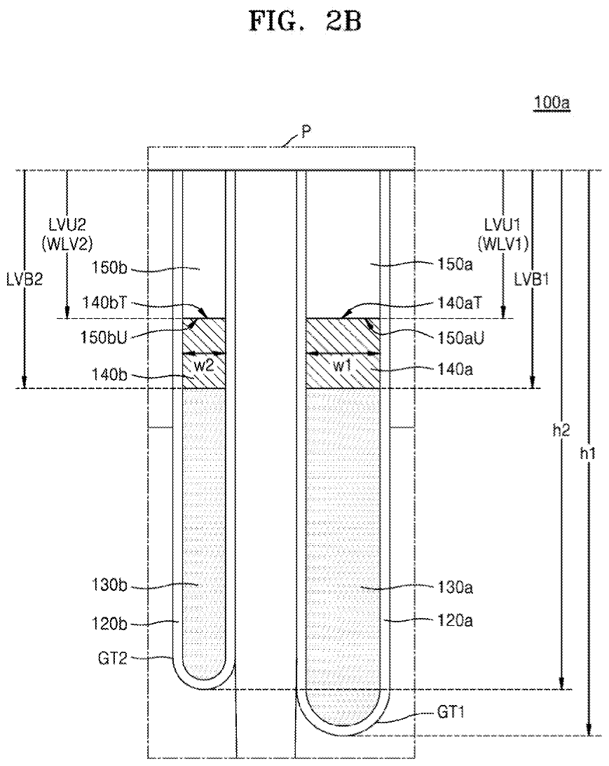

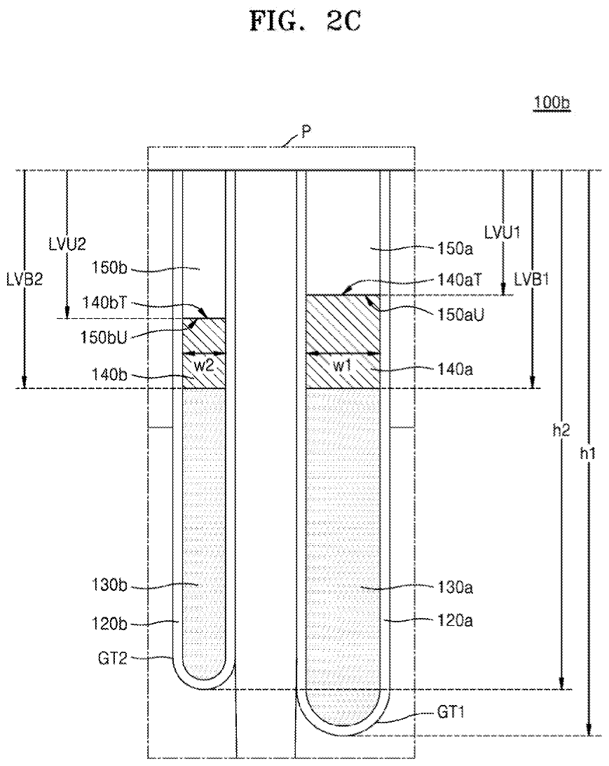

FIG. 1 is a plan view of components of an integrated circuit (IC) device 100 according to example embodiments. In addition, FIG. 2A is a cross-sectional view of components of FIG. 1, taken along line X-X′ and Y-Y′.

Referring to FIGS. 1 and 2A, the IC device 100, 100a may include a substrate 110 including a plurality of active regions AC defined by a device isolation layer 112 and a plurality of gate trenches GT extending across the active regions AC. The integrated circuit device 100a shown in FIG. 2 is an example embodiment of the integrated circuit device of FIG. 1.

The active regions AC may be repeatedly apart from each other in a first horizontal direction (an X direction) and a second horizontal direction (a Y direction) orthogonal to the first horizontal direction (the X direction), respectively, and may have a shape extending in an oblique direction to have a major axis in one direction (a Q direction in FIG. 1), different from the first horizontal direction (the X direction) and the second horizontal direction (the Y direction). The gate trenches GT may have a plurality of line shapes extending parallel to each other in the first horizontal direction (the X direction). The gate trenches GT may include a first gate trench GT1 and a second gate trench GT2 apart from the first gate trench GT1 in the first horizontal direction (the X direction).

The device isolation layer 112 may include a silicon oxide layer, or a silicon nitride layer. As used herein, the term “or” is not an exclusive term, e.g., “A or B” would include A, B, or A and B.

In the first gate trench GT1, a gate dielectric layer 120, a first gate structure GS1 filling a portion of the first gate trench GT1 on the gate dielectric layer 120, and a first insulating capping layer 150a covering the first gate structure GS1 in the gate trench GT1 are formed. A level of a portion of a bottom surface of the first gate trench GT1 exposed to the substrate 110 may be higher than a level of a portion of the device isolation layer 112 exposed to the substrate 110. Accordingly, a bottom surface of the first gate structure GS1 may have a concavo-convex shape corresponding to a bottom profile of the first gate trench GT1. Accordingly, transistors having a saddle fin structure (saddle FINFETs) may be in the active regions AC.

A first gate dielectric layer 120a may cover an inner surface of the first gate trench GT1 to contact the active region AC and the device isolation layer 112. A plurality of gate dielectric layers 120a and 120b may include a silicon oxide layer, a silicon nitride layer, a silicon oxynitride layer, an oxide/nitride/oxide (ONO) layer, or a high-k dielectric film having a dielectric constant higher than that of the silicon oxide layer. The high-k dielectric film may have a dielectric constant of about 10 to about 25, and may include, e.g., HfO₂, Al₂O₃, HfAlO₃, Ta₂O₃, or TiO₂.

A plurality of insulating capping layers 150a and 150b may include a silicon nitride layer, a silicon oxynitride layer, or a silicon oxide layer.

The gate structure GS may have gate sidewalls facing the active region AC, and the first insulating capping layer 150a and may include insulating sidewall portions facing the gate dielectric layer 120. Source/drain regions SD may be on both sides of the gate structure GS in the active regions AC.

The gate structure GS may include a lower gate line 130 having a first work function and an upper gate line 150 having a second work function lower than the first work function. As each constituent material may have a different work function, a threshold voltage of the gate electrode may be precisely controlled. The lower gate lines 130a and 130b may include metal, metal nitride, or metal carbide. In some embodiments, the lower gate lines 130a and 130b may include Ti, TiN, Ta, TaN, W, WN, TiSiN, or WSiN. The first and second upper gate lines 140a and 140b may include doped polysilicon.

The above description of the first gate trench GT1 and the first gate structure GS1 buried in the first gate trench GT1 may also be applied to the second gate trench GT2 and the second gate structures GS buried in the second gate trench GT2.

FIGS. 2B and 2C are cross-sectional views of components of IC devices 100a and 100b according to example embodiments. FIGS. 2B and 2C are enlarged views of components of portions corresponding to portion “P” of FIG. 2A. In FIGS. 2B and 2C, like reference numerals in FIGS. 1 and 2A denote like elements and detailed descriptions thereof are omitted here.

Referring to FIG. 2B together with FIG. 2A, the first gate trench GT1 and the second gate trench GT2 apart from the first gate trench GT1 in the first horizontal direction (the X direction) are in the substrate 110 of the IC device 100a. In the first gate trench G1 and the second gate trench G2, lower surfaces thereof may have profiles having a certain curvature.

According to an embodiment, a depth h1 of the first gate trench GT1 in a vertical direction may be greater than a depth h2 of the second gate trench GT2 in the vertical direction. In this case, the depth h1 of the first gate trench GT1 in the vertical direction and the depth h2 of the second gate trench GT2 in the vertical direction may be depths defined based on an upper surface of the first insulating capping layer 150a and an upper surface of the second insulating capping layer 150b.

According to an embodiment, the IC device 100a may include a first gate dielectric layer 120a covering an inner surface of the first gate trench GT1. In this case, the gate dielectric layer 120a may be on an inner wall of the first gate trench GT1, while maintaining a conformal thickness. Also, the IC device 100a may include a second gate dielectric layer 120b covering an inner surface of the second gate trench GT2. A thickness and material of the second gate dielectric layer 120b may be substantially the same as those of the first gate dielectric layer 120a. The gate dielectric layers 120a and 120b may include fixed charges trapped with a certain density. In this specification, the term “fixed charges” may refer to fixed charges introduced into the gate dielectric layers 120a and 120b through an intended process. Here, the fixed charges may include positive charges or negative charges.

According to an embodiment, the IC device 100a may include a first lower gate line 130a filling a portion of the first gate trench GT1 on the first gate dielectric layer 120a and a second lower gate line 130b filling a portion of the second gate trench GT2 on the second gate dielectric layer 120b. In this case, upper surfaces of the first lower gate line 130a and the second lower gate line 130b may be at a vertical level lower than an upper surface of the active region AC. In addition, lower surfaces of the first lower gate line 130a and the second lower gate line 130b may overlap the active region AC.

The IC device 100a may include a first upper gate line 140a on the first lower gate line 130a and a second upper gate line 140b on the second lower gate line 130b. In FIG. 2B, the upper surface of the first lower gate line 130a is in contact with a lower surface of the first upper gate line 140a. Another structure may be located between the first lower gate line 130a and the first upper gate lines 140a.

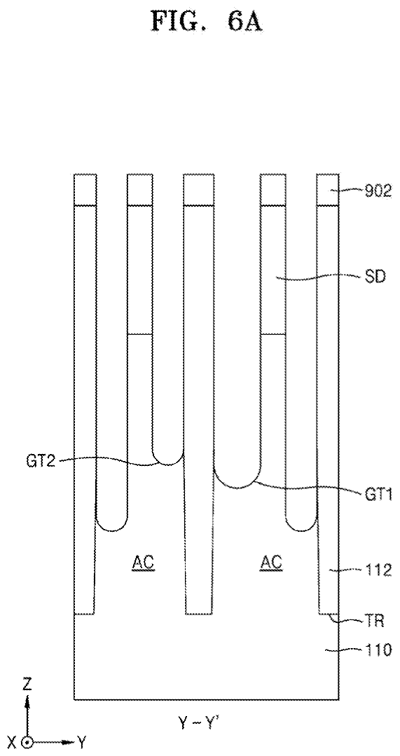

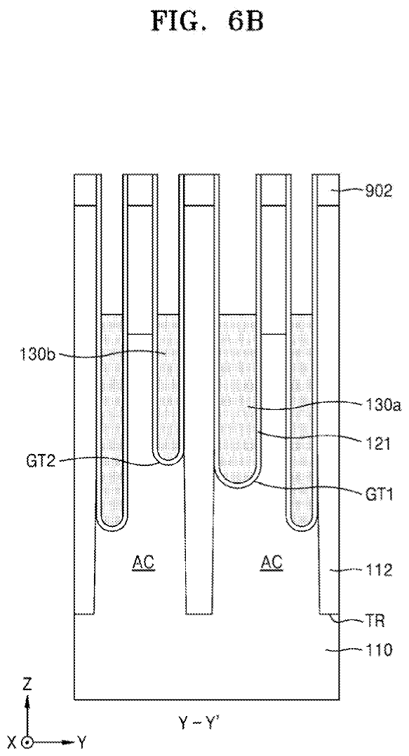

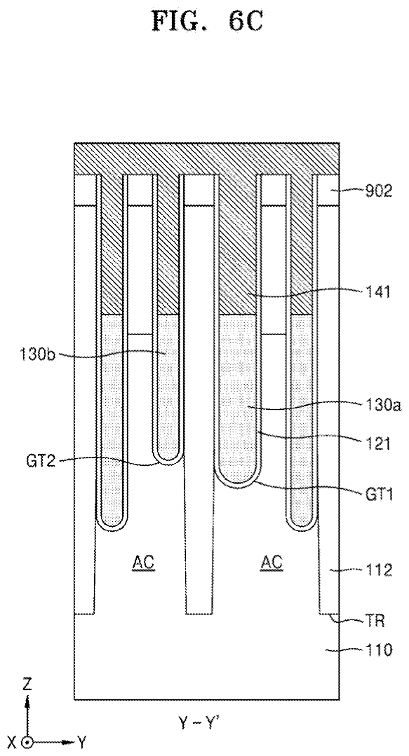

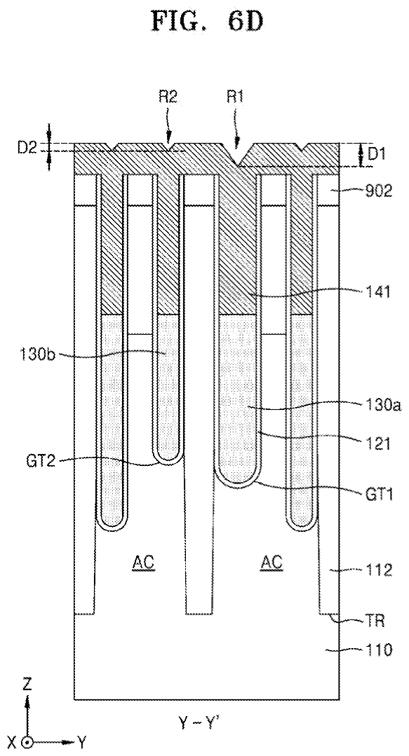

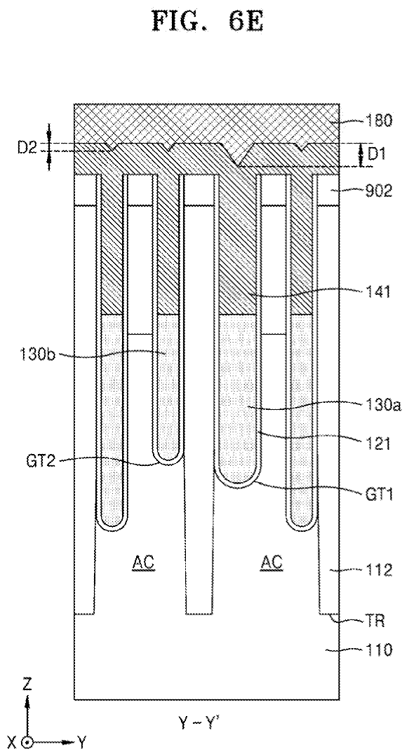

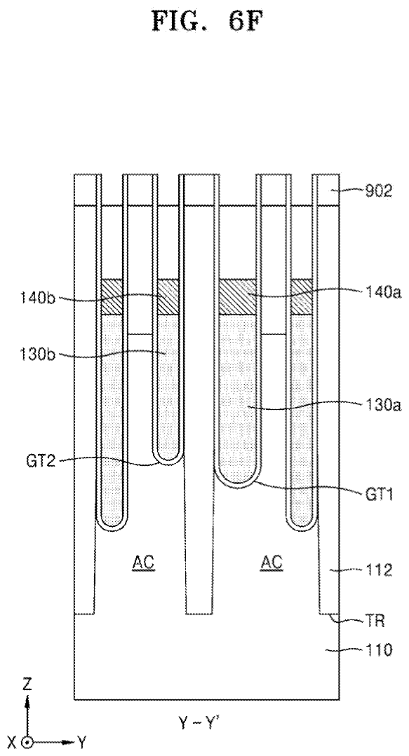

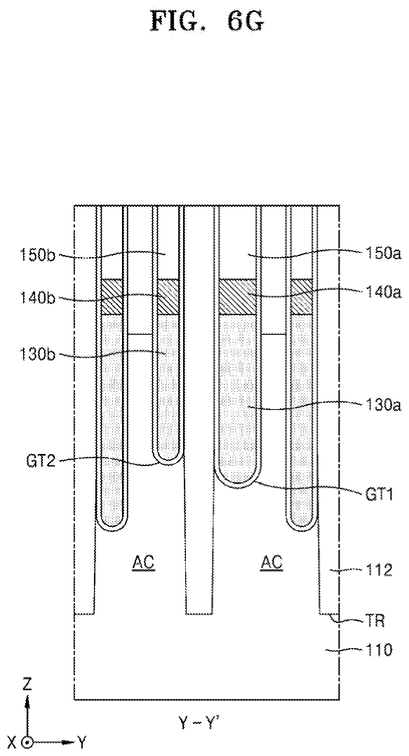

According to an embodiment, a first width w1 of the first upper gate line 140a in the first horizontal direction (the X direction) may be greater than a second width w2 of the second upper gate line 140b in the first horizontal direction (the X direction). Also, a vertical level LVU1 of a first upper surface 140aT of the first upper gate line 140a may be substantially equal to a vertical level LVU2 of a second upper surface 140bT of the second upper gate line 140b, and the first upper surface 140aT of the first upper gate line 140a and the second upper surface 140bT of the second upper gate line 140b may be flat. As shown in FIGS. 6E and 6F, in order to form the first upper gate line 140a, an upper gate layer 141 stacked on the first lower gate line 130a may be etched. In this case, as the first width w1 of the first upper gate line 140a is greater, an area exposed in an etching process may be large, so that the amount of etching per unit time may increase.

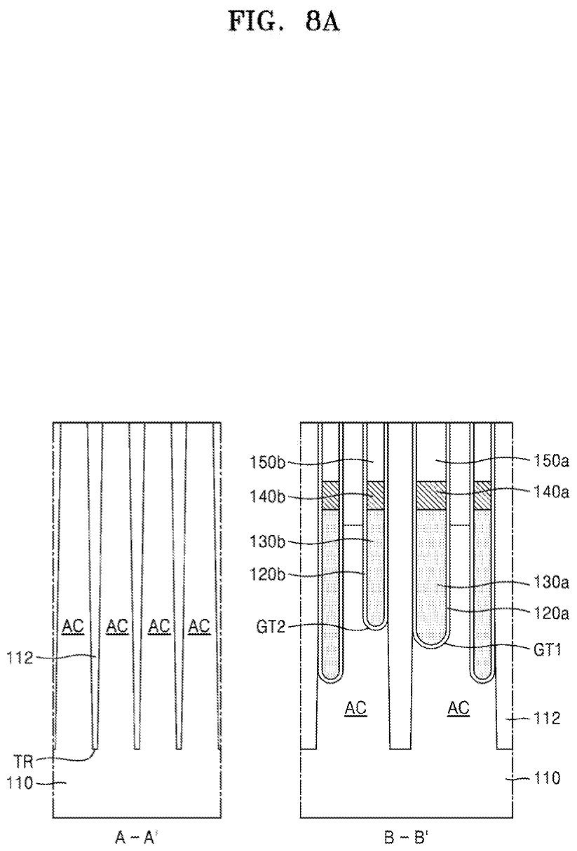

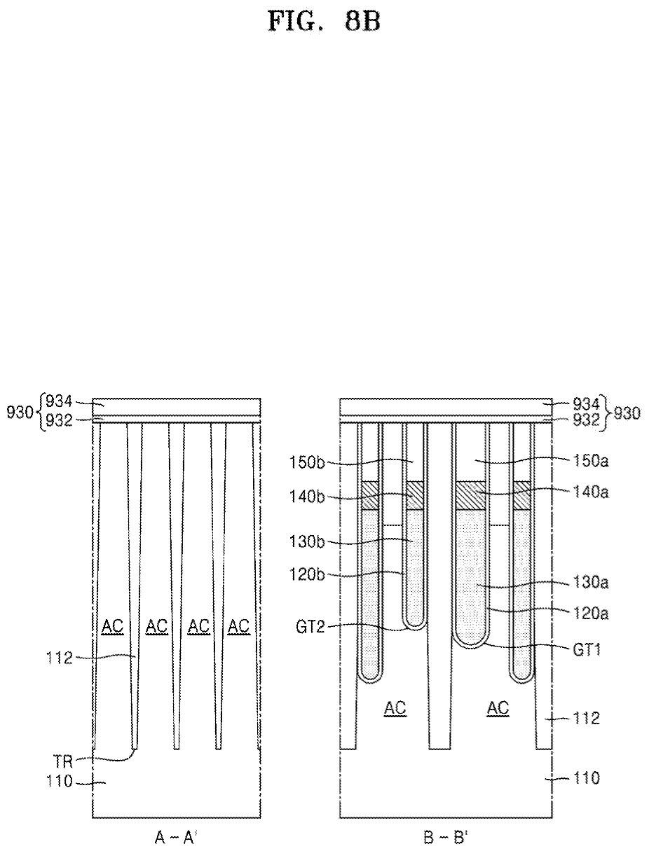

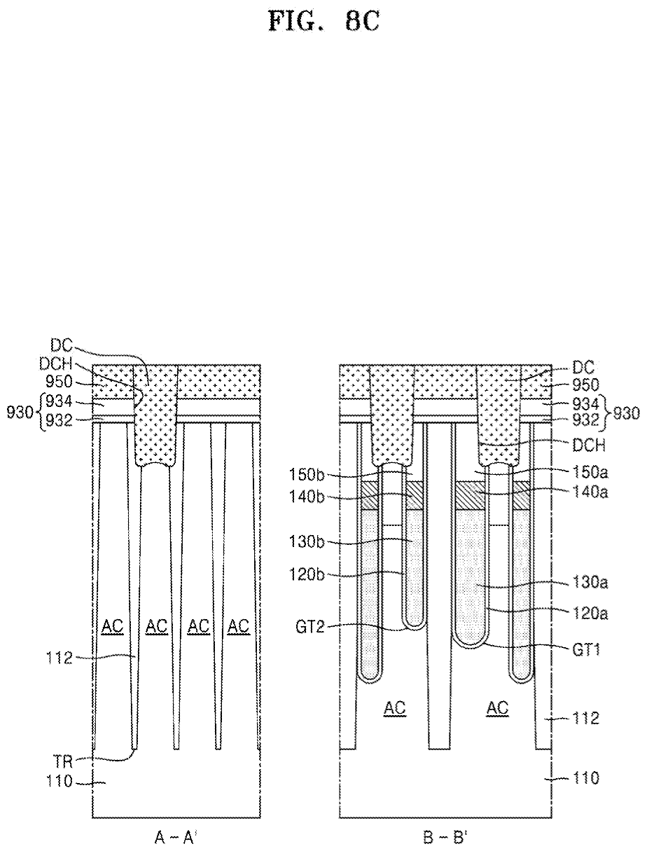

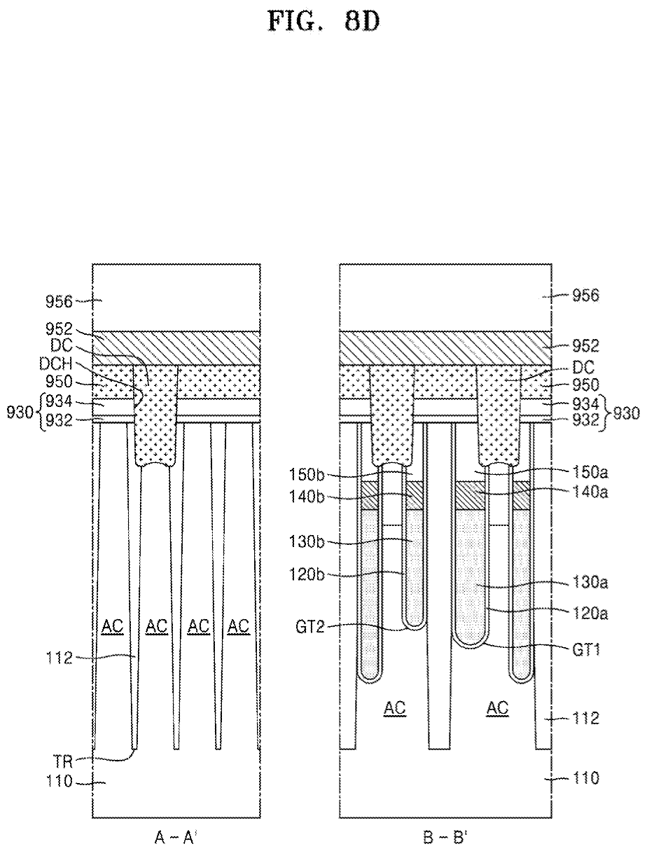

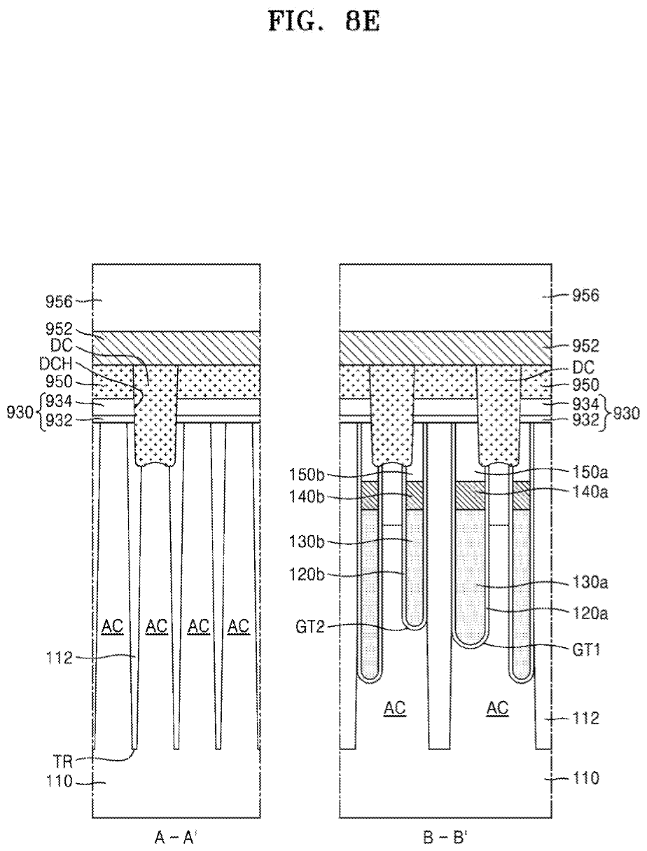

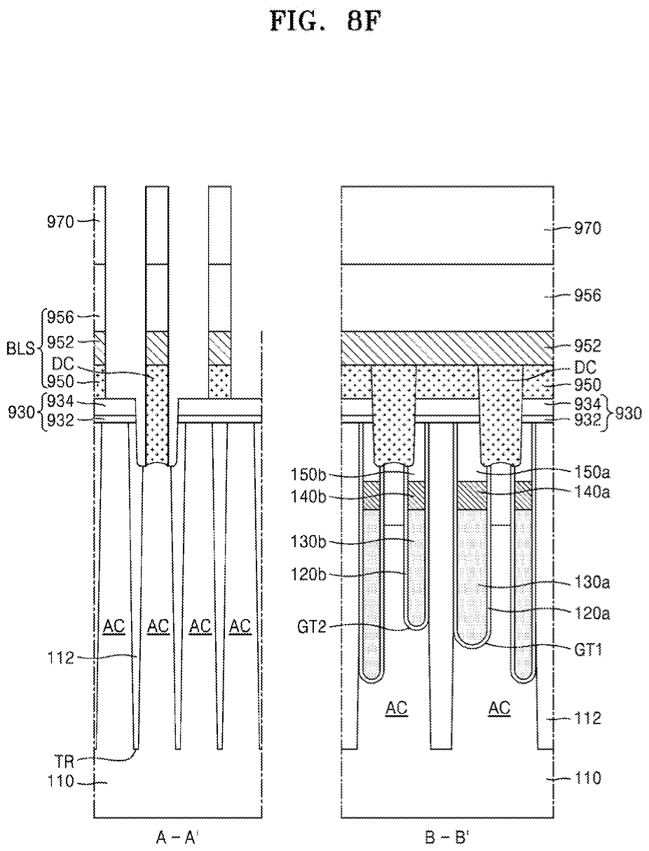

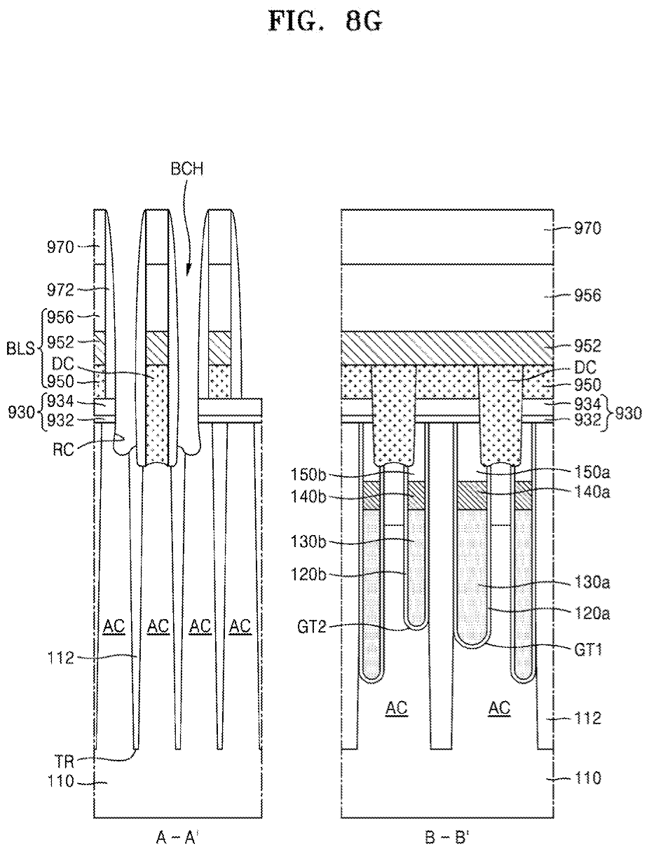

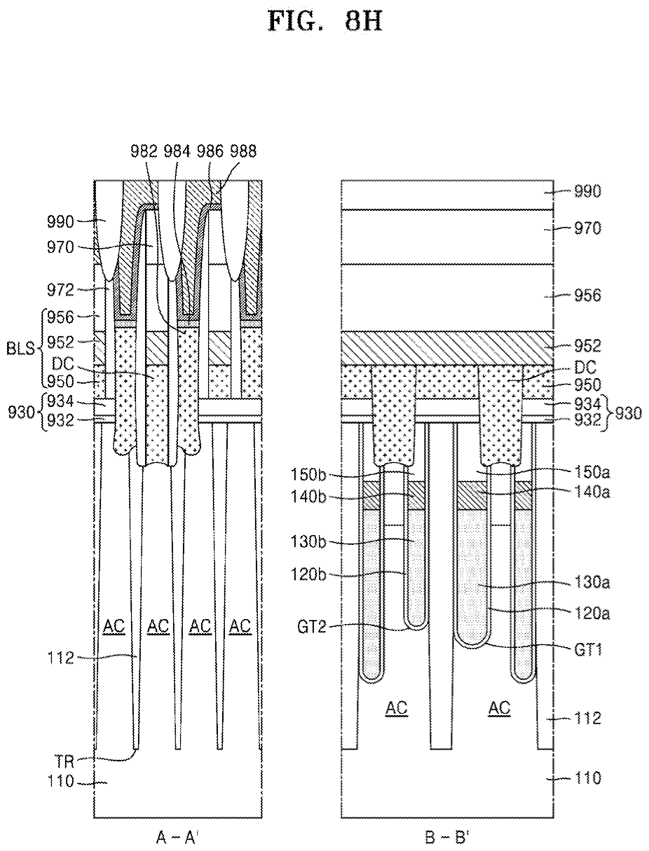

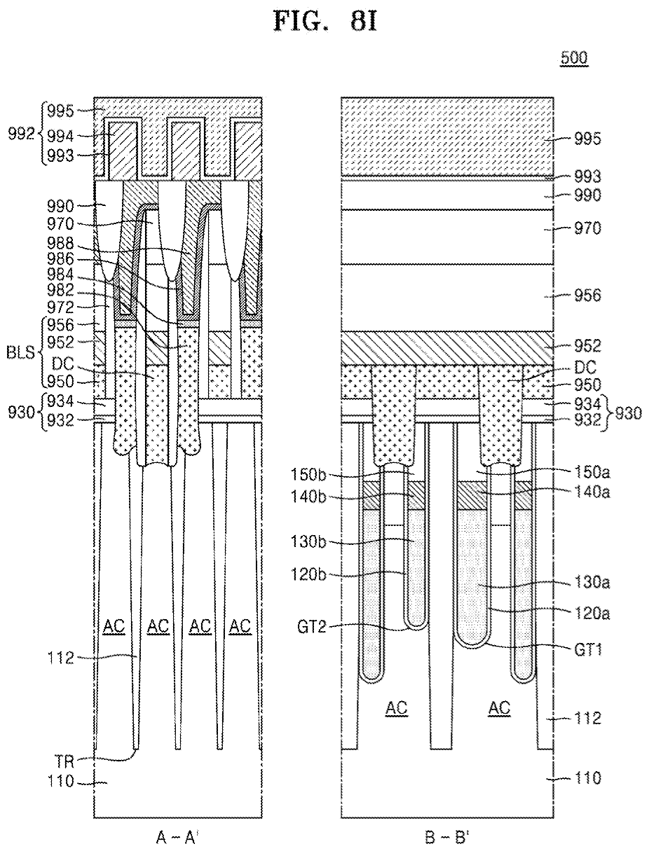

In this case, the vertical level LVU1 of the upper surface of the first upper gate line 140a having the first width w1 being large in the first horizontal direction may be lower than the vertical level LVU2 of the upper surface of the second upper gate line 140b having the second width w2 being small in the first horizontal direction. Also, in the process of etching the upper gate layer 141 shown in FIG. 6E, the first upper surface 140aT of the first upper gate line 140a may have a downwardly concave profile rather than a flat cross section. When the first upper surface 140aT of the first upper gate line 140a has a downwardly concave profile, a probability that a corner portion of the first upper surface 140aT of the first upper gate line 140a contacts a direct contact DC shown in FIG. 8H may increase. Therefore, because the first upper surface 140aT of the first upper gate line 140a may have a flat profile, the probability of contacting the direct DC to cause a leakage current may be reduced.

According to a general etching process, the upper gate layer 141 (refer to FIG. 6E) may be etched so that the upper surfaces of the first and second upper gate lines 140a and 140b have a downwardly concavely rounded profile. In the present embodiment, recesses R1 and R2 (e.g., first and second recesses R1 and R2, referring to FIG. 6D) having an inverted triangle shape in which a proportion of a sacrificial layer 180 (refer to FIG. 6E) increases toward the center of the recesses R1 and R2 may reduce the degree of etching of a central portion of the gate trenches GT1 and GT2 (e.g., first and second gate trenches GT1 and GT2) per unit time. Accordingly, the first and second upper gate lines 140a and 140b may have a flat profile or an upwardly convex profile.

According to an embodiment, a vertical level LVB1 of a lower surface of the first upper gate line 140a may be substantially equal to a vertical level LVB2 of a lower surface of the second upper gate line 140b.

According to an embodiment, the IC device 100a may include the first insulating capping layer 150a on the first upper gate line 140a and the second insulating capping layer 150b on the second upper gate line 140b and having a width smaller than that of the first insulating capping layer 150a. Although an upper surface of the first upper gate line 140a is shown to be in contact with a lower surface of the first insulating capping layer 150a in the drawing, another structure may be located between the upper surface of the first upper gate line 140a and the first insulating capping layer 150a. However, even if another structure is located between the upper surface of the first upper gate line 140a and the lower surface of the first insulating capping layer 150a, a gap between the first upper gate line 140a and the first insulating capping layer 150a may be uniform. In this case, because the vertical level LVU1 of the upper surface of the first upper gate line 140a is substantially equal to the vertical level LVU2 of the upper surface of the second upper gate line 140b, a vertical level of the first insulating capping layer 150a may be substantially equal to a vertical level of the second insulating capping layer 150b. In addition, because the first upper surface 140aT of the first upper gate line 140a and the second upper surface 140bT of the second upper gate line 140b may be flat, a first lower surface 150aU of the first insulating capping layer 150a and a second lower surface 150bU of the second insulating capping layer 150b may be flat.

According to an embodiment, because the first upper surface 140aT of the first upper gate line 140a may be flat, the uppermost end of a sidewall of the first upper gate line 140a contacting the first gate dielectric layer 120a may be substantially equal to the uppermost surface of the first upper gate line 140a. Therefore, a vertical level WLV1 of the uppermost end of the sidewall of the first upper gate line 140a contacting the first gate dielectric layer 120a may be substantially equal to the vertical level LVU1 of the uppermost surface of the first upper gate line 140a. Similarly, a vertical level WLV2 of the upper most end of the sidewall of the second upper gate line 140b contacting the second gate dielectric layer 120b may also be substantially equal to the vertical level LVU2 of the uppermost surface of the first upper gate line 140a.

An IC device 100b shown in FIG. 2C may be substantially the same as or similar to the IC device 100a shown in FIG. 2B, except that the vertical level LVU1 of the upper surface of the first upper gate line 140a may be higher than the vertical level LVU2 of the upper surface of the second upper gate line 140b.

As described above with reference to FIG. 2B, in order to form the first upper gate line 140a, the upper gate layer 141 stacked on the first lower gate line 130a may be etched. In this case, as the width of the gate trenches GT1 and GT2 increases, an exposed area of the upper gate layer 141 may increase during an etching process, thereby increasing an etch rate. However, as is described below, when the sacrificial layer 180 having a different etching selectivity is stacked on the upper gate layer 141, the degree of etching of the upper gate layer 141 per unit time in the etching process may be lowered. Therefore, because the amount of the sacrificial layer 180 on the first gate trench GT1 that is wider than the second gate trench GT2 is greater, the degree of etching of the upper gate layer 141 on the first gate trench GT1 may be lower. Accordingly, the vertical level LVU1 of the upper surface of the first upper gate line 140a may be higher than the vertical level LVU2 of the upper surface of the second upper gate line 140b.

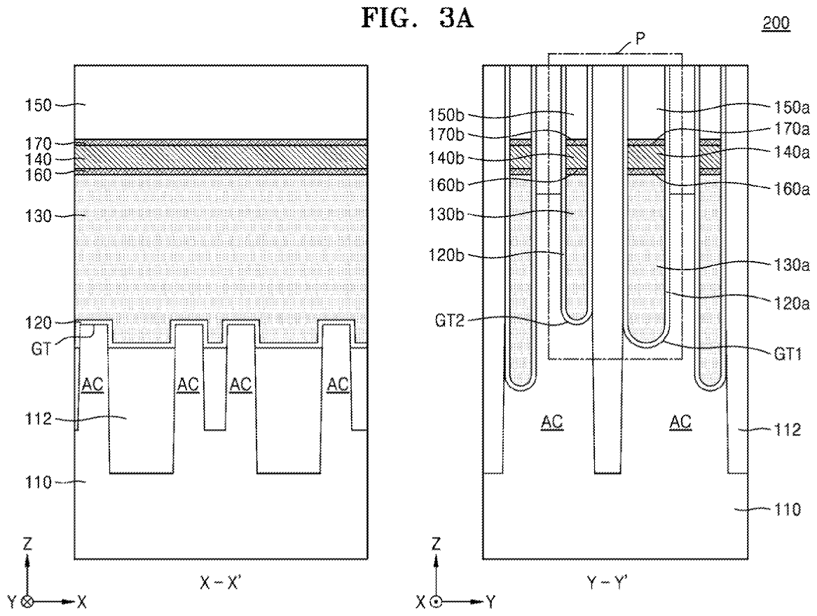

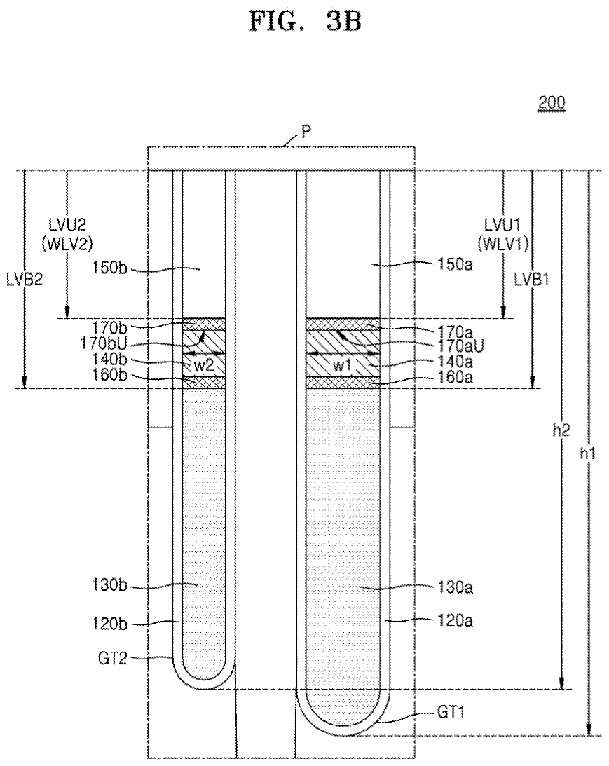

FIG. 3A is a cross-sectional view showing components, taken along lines X-X′ and Y-Y′ of FIG. 1 according to an example embodiment, and FIG. 3B is a cross-sectional view of components of an IC device 200.

The IC device 200 shown in FIGS. 3A and 3B may be substantially the same as or similar to the IC device 100a shown in FIGS. 2A and 2B, except that the IC device 200 may include lower blocking layers 160a and 160b respectively on lower surfaces of the first and second upper gate lines 140a and 140b and upper blocking layers 170a and 170b respectively on upper surfaces of the first and second upper gate lines 140a and 140b. Hereinafter, descriptions of the same components as those of the IC device 100a shown in FIGS. 2A and 2B are omitted.

The lower blocking layers 160a and 160b may be located between the lower gate lines 130a and 130b and the first and second upper gate lines 140a and 140b, respectively. The lower blocking layers 160a and 160b between the lower gate lines 130a and 130b and the first and second upper gate lines 140a and 140b may prevent constituent materials of the lower gate lines 130a and 130b and the first and second upper gate lines 140a and 140b from diffusing to each other or reacting with each other. In some embodiments, the lower blocking layers 160a and 160b may prevent a reaction between metal included in the lower gate lines 130a and 130b and silicon included in the first and second upper gate lines 140a and 140b to prevent formation of a metal silicide layer between the lower gate lines 130a and 130b and the first and second upper gate lines 140a and 140b.

The upper blocking layers 170a and 170b may be located between the first and second upper gate lines 140a and 140b and the first and second insulating capping layers 150a and 150b. The upper blocking layers 170a and 170b may cover at least a portion of upper surfaces of the first and second upper gate lines 140a and 140b. The upper blocking layers 170a and 170b between the first and second upper gate lines 140a and 140b and the first and second insulating capping layers 150a and 150b may prevent constituent materials of the first and second upper gate lines 140a and 140b and the first and second insulating capping layers 150a and 160b from diffusing to each other or reacting with each other.

According to an embodiment, a lower surface of the first upper blocking layer 160a and a lower surface of the second upper blocking layer 160b may be flat. Because upper surfaces of the first and second upper gate lines 140a and 140b covered by the upper blocking layers 170a and 170b may be flat, lower surfaces of the upper blocking layers 170a and 170b may also be flat. In addition, the vertical level LVU1 of the upper surface of the first upper blocking layer 170a from an upper surface of the device isolation layer 112 may be substantially equal to the vertical level LVU2 from the upper surface of the device isolation layer 112 to the lower surface of the second upper blocking layer 170b. In addition, the vertical level LVB1 of the lower surface of the first lower blocking layer 160a from the upper surface of the device isolation layer 112 may be equal to the vertical level LVB2 from the upper surface of the device isolation layer 112 to the lower surface of the second lower blocking layer 160b.

The lower blocking layers 160a and 160b and the upper blocking layers 170a and 170b may include different materials. The lower blocking layers 160a and 160b and the upper blocking layers 170a and 170b may each include a conductive material, or a dielectric material. In some embodiments, the lower blocking layers 160a and 160b may include metal, and the upper blocking layers 170a and 170b may not include metal. In some other embodiments, at least one of the lower blocking layers 160a and 160b and the upper blocking layers 170a and 170b may include an oxide layer, or a nitride layer, including metal. In some other embodiments, at least one of the lower blocking layers 160a and 160b and the upper blocking layers 170a and 170b may include an oxide layer, or a nitride layer, not including metal. In some other embodiments, the lower blocking layers 160a and 160b may include a multilayer including metal, and the upper blocking layers 170a and 170b may include a single layer not including metal. Each of the lower blocking layers 160a and 160b and the upper blocking layers 170a and 170b may have a thickness of about 1 Å to about 20 Å.

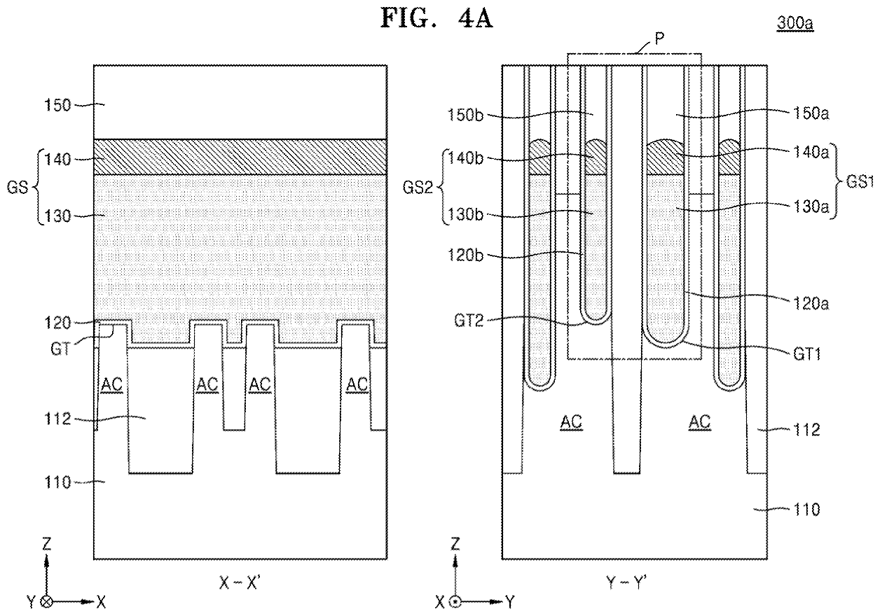

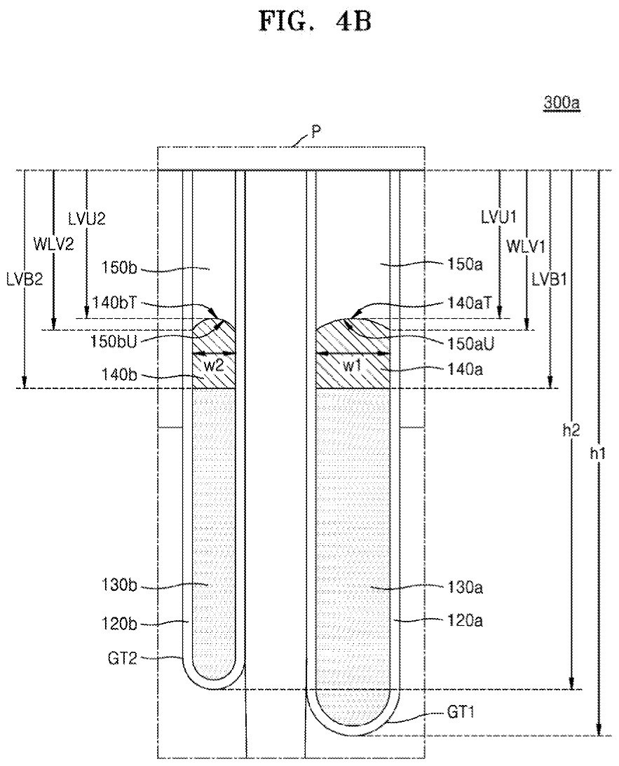

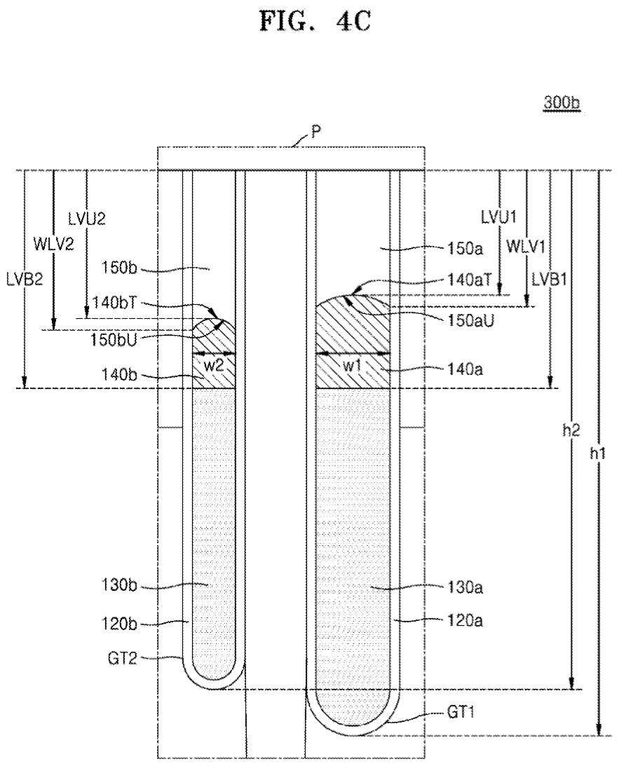

FIG. 4A is a cross-sectional view showing components, taken along lines X-X′ and Y-Y′ of FIG. 1 according to an example embodiment, and FIGS. 4B and 4C are cross-sectional views of components of IC devices 300a and 300b according to various embodiments.

The IC device 300a shown in FIGS. 4A and 4B may be substantially the same as or similar to the IC device 100a shown in FIGS. 2A and 2B, except that first and second upper surfaces 140aT and 140bT of the first and second upper gate lines 140a and 140b may have an upwardly convex rounded profile. Hereinafter, descriptions of the same components as those of the IC device 100a shown in FIGS. 2A and 2B are omitted.

According to an embodiment, the first width w1 of the first upper gate line 140a in the first horizontal direction (the X direction) may be greater than the second width w2 of the second upper gate line 140b in the first horizontal direction (the X direction). Also, a vertical level LVU1 of the first upper surface 140aT of the first upper gate line 140a may be substantially equal to a vertical level LVU2 of the second upper surface 140bT of the second upper gate line 140b, and the first upper surface 140aT of the first upper gate line 140a and the second upper surface 140bT of the second upper gate line 140b may have an upwardly convexly rounded profile.

As described above with reference to FIG. 2B, in order to form the first upper gate line 140a, the upper gate layer 141 stacked on the first lower gate line 130a may be etched. Here, as the width of the gate trenches GT1 and GT2 increases, an area exposed in an etching process may be large and an etch rate may increase. Therefore, in order to reduce the degree of etching of the upper gate layer 141 per unit time, the sacrificial layer 180 having a different etching selectivity may be stacked on the upper gate layer 141. When the degree of etching of the upper gate layer 141 per unit time is lower than a certain value, the first and second upper surfaces 140aT and 140bT of the first and second upper gate lines 140a and 140b may have an upwardly convexly rounded profile.

Because the first and second upper surfaces 140aT and 140bT of the first and second upper gate lines 140a and 140b may have an upwardly convexly rounded profile, the vertical level WLV1 of the uppermost end of the sidewall of the first upper gate line 140a contacting the first gate dielectric layer 120a may be lower than the vertical level LVU1 of the uppermost surface of the first upper gate line 140a. Similarly, the vertical level WLV2 of the uppermost end of the sidewall of the second upper gate line 140b contacting the second gate dielectric layer 120b may be lower than the vertical level LVU2 of the uppermost surface of the second upper gate line 140b.

In addition, as the etch rate of the upper gate layer 141 increases, the upper surface of the first upper gate line 140a may have a downwardly concave profile. When the upper surface of the first upper gate line 140a has a downwardly concave profile, a probability of contacting the direct contact DC shown in FIG. 8H may increase. Accordingly, because the first upper surface 140aT of the first upper gate line 140a may have an upwardly convexly rounded profile, a probability of contacting the direct DC to cause a leakage current may be reduced.

The IC device 300b shown in FIG. 4C may be substantially the same as or similar to the IC device 300a shown in FIG. 4B, except that the vertical level LVU1 of the uppermost surface of the first upper gate line 140a may be higher than the vertical level LVU2 of the uppermost surface of the second upper gate line 140b.

As described above with reference to FIG. 2B, when the sacrificial layer 180 having a different etching selectivity is stacked on the upper gate layer 141, the degree of etching of the upper gate layer 141 per unit time in the etching process may be lowered. Accordingly, the vertical level LVU1 of the uppermost surface of the first upper gate line 140a may be higher than the vertical level LVU2 of the uppermost surface of the second upper gate line 140b. In this case, compared to the embodiment of FIG. 2B, the depth and shape of the recesses R1 and R2 in which the sacrificial layer 180 is buried may be different from each other. As the depth of the first recess R1 increases, the amount of the sacrificial layer 180 in the upper portion of the first gate trench GT1 may increase and the amount of the first upper gate line 140a to be etched may be reduced. Accordingly, the vertical level LVU1 of the uppermost surface of the first upper gate line 140a may increase.

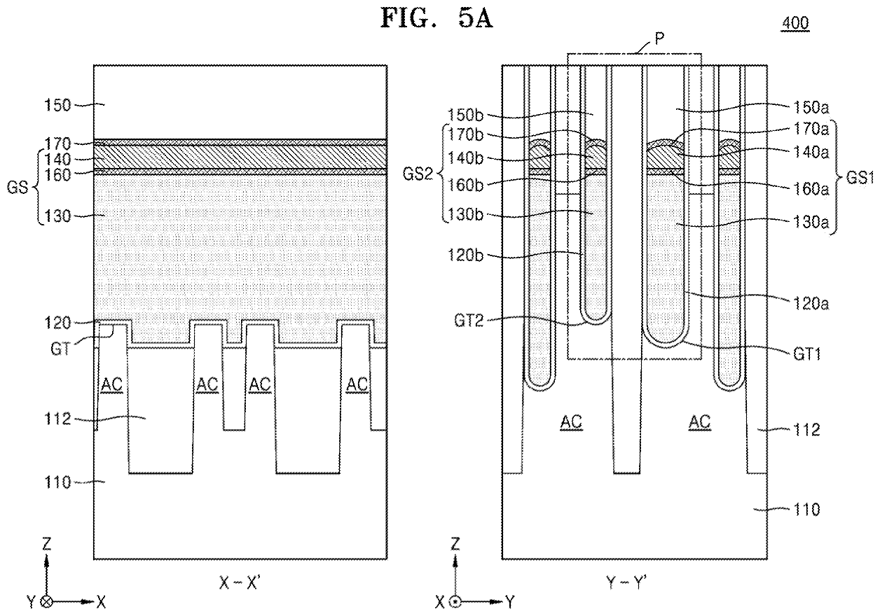

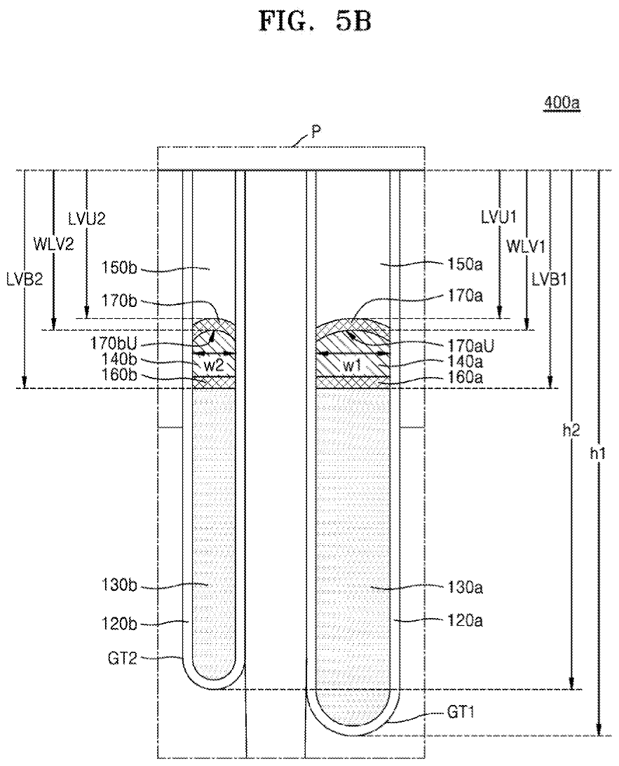

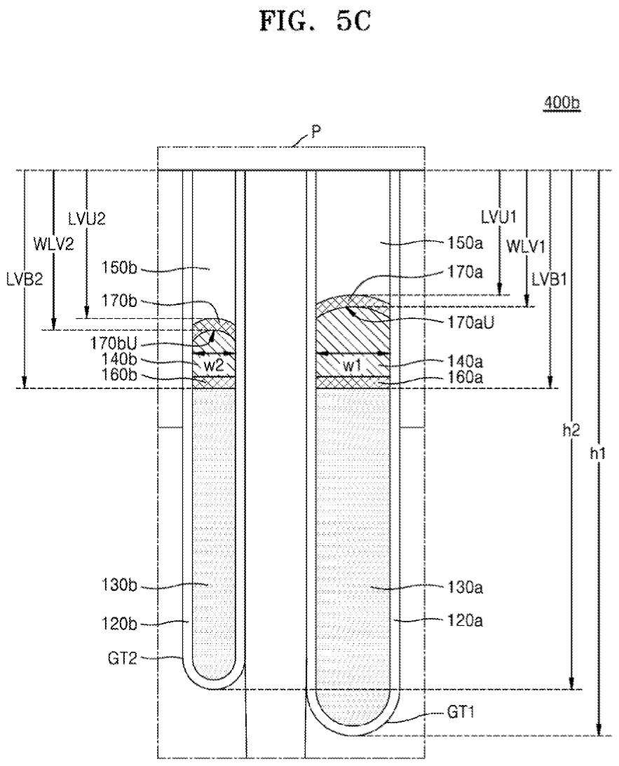

FIG. 5A is a cross-sectional view of components, taken along lines X-X′ and Y-Y′ of FIG. 1 according to an example embodiment, and FIGS. 5B and 5C are cross-sectional views of components of IC devices 400a and 400b according to example embodiments.

The IC device 400a shown in FIG. 5B may be substantially the same as or similar to the IC device 300a shown in FIG. 4B, except that the IC device 400a may include the lower blocking layers 160a and 160b respectively on lower surfaces of the first and second upper gate lines 140a and 140b and the upper blocking layers 170a and 170b respectively on upper surfaces of the first and second upper gate lines 140a and 140b. The lower blocking layers 160a and 160b and the upper blocking layers 170a and 170b shown in FIGS. 5A and 5B may be the same as the lower blocking layers 160a and 160b and the upper blocking layers 170a and 170b described above with reference to FIGS. 3A and 3B. Hereinafter, descriptions of the same components as those of the IC device 300a shown in FIG. 4B and the IC device 200 shown in FIG. 3A are omitted or simplified.

The upper blocking layers 170a and 170b may cover at least a portion of upper surfaces of the first and second upper gate lines 140a and 140b. A lower surface of the first upper blocking layer 170a covering at least a portion of the upper surface of the first upper gate line 140a may have a downwardly concavely rounded profile. Similarly, a lower surface of the second upper blocking layer 170b covering at least a portion of the upper surface of the second upper gate line 140b may also have a downwardly concavely rounded profile. Here, as shown in FIG. 5A, the vertical level LVU2 of the upper surface of the second upper blocking layer 170b from the upper surface of the device isolation layer 112 may be substantially equal to the vertical level LVU1 from the upper surface of the device isolation layer 112 to the lower surface of the first upper blocking layer 170a. The vertical level LVU2 of the lower surface of the second upper blocking layer 170b may be substantially different from the vertical level LVU1 of the lower surface of the first upper blocking layer 170a. In addition, the vertical level LVB1 of the lower surface of the first lower blocking layer 160a from the upper surface of the device isolation layer 112 may be substantially equal to the vertical level LVB2 of the lower surface of the second lower blocking layer 160b from the upper surface of the device isolation layer 112.

The upper blocking layers 160a and 160b and the lower blocking layers 170a and 170b shown in FIG. 5A may be the same as the upper blocking layers 160a and 160b and the lower blocking layers 170a and 170b described above with reference to FIGS. 3A and 3B.

The IC device 400b shown in FIG. 5C may be substantially the same as the IC device 400a shown in FIG. 5B, except that the vertical level LVU1 of the upper surface of the first upper blocking layer 170a from the upper surface of the device isolation layer 112 may be higher than the vertical level LVU2 of the upper surface of the second upper blocking layer 170b from the upper surface of the device isolation layer 112. Therefore, descriptions of the same reference numerals as those described above with reference to FIGS. 5A and 5B are omitted.

As shown in FIG. 5C, the vertical level of the upper surface of the first upper gate line 140a may be higher than the vertical level of the upper surface of the second upper gate line 140b. Subsequently, as illustrated in the process of FIGS. 6D and 6E, the sacrificial layer 180 having a different etching selectivity may be on the upper surface of the upper gate layer 141. Here, according to a depth of the recesses R1 and R2 in which the sacrificial layer 180 is buried and an etch rate of the sacrificial layer 180, the vertical level of the upper surface of the first upper gate line 140a may be higher than the vertical level of the upper surface of the second upper gate line 140b. When the amount of the sacrificial layer 180 on the first gate trench GT1 is large, the degree of etching of the upper gate layer 141 buried in the first gate trench GT1 may be small, so that the vertical level of the upper surface of the first upper gate line 140a may be high. Accordingly, the vertical level LVU1 of the upper surface of the first upper blocking layer 170a on the upper surface of the first upper gate line 140a may be higher than the vertical level LVU2 of the upper surface of the second upper blocking layer 170b.

FIGS. 6A to 6G are cross-sectional views of a method of manufacturing an IC device according to example embodiments.

Referring to FIG. 6A, device isolation trenches TR defining the active regions AC may be on the substrate 110. The device isolation layer 112 filling the device isolation trench TR around the active regions AC may be formed, and a plurality of source/drain regions SD (refer to FIG. 1) may be in the active regions AC. In order to form the device isolation layer 112, an atomic layer deposition (ALD) process, a chemical vapor deposition (CVD) process, a radical oxidation process, or a natural oxidation process may be used.

A plurality of mask line patterns 902 apart from each other and extending parallel to each other in the first horizontal direction (the X direction) may be on the active regions AC and the isolation layer 112. The mask line patterns 902 may include a hard mask pattern having a single layer structure or a multilayer structure. In an implementation, the mask line patterns 902 may include an oxide layer, or a nitride layer. The gate trenches GT1 and GT2 extending parallel to each other in the first horizontal direction (the X direction) may etch the active regions AC and the device isolation layer 112 may use the mask line patterns 902 as an etch mask. In this case, the first gate trench GT1 may have a relatively wider width and a greater depth than those of the second gate trench GT2. In an implementation, as illustrated in FIG. 6A, a horizontal distance between the sides of the first gate trench GT1 may be larger than a horizontal distance between the sides of the second gate trench GT2. In an implementation, a vertical distance between the bottom of the first gate trench GT1 and the isolation trench TR may be larger than a vertical distance between the bottom of the second gate trench GT2 and the isolation trench TR.

Referring to FIG. 6B, the gate dielectric layer 120 covering inner surfaces of each of the gate trenches GT1 and GT2 may be formed. A thermal oxidation process, or an ALD process, may be used to form the gate dielectric layer 120.

Thereafter, the lower gate lines 130a and 130b filling portions of the gate trenches GT1 and GT2 may be formed. After the lower gate lines 130a and 130b are formed, upper surfaces of the mask line patterns 902 may be exposed.

Referring to FIG. 6C, the upper gate layer 141 may cover the upper surfaces of the lower gate lines 130a and 130b and the upper surface of the mask line pattern 902. In this case, the upper gate layer 141 may fill spaces of the gate trenches GT1 and GT2 remaining after the lower gate lines 130a and 130b are buried. The upper gate layer 141 may include doped polysilicon.

Referring to FIG. 6D, the recesses R1 and R2 may be in the upper gate layer 141. In this case, the first recess R1 may overlap the first gate trench GT1, and a width of the first recess R1 may be smaller than that of the first gate trench GT1. The second recess R2 may overlap the second gate trench GT2, and a width of the second recess R2 may be smaller than that of the second gate trench GT2. FIG. 6D shows that a depth D1 of the first recess R1 and a depth D2 of the second recess R2 may not reach the gate trenches GT1 and GT2. According to some embodiments, the first recess R1 or the second recess R2 may penetrate into the gate trenches GT1 and GT2. The depth D1 of the first recess R1 may be greater than the depth D1 of the second recess R2.

Referring to FIGS. 6E and 6F, the sacrificial layer 180 may be on the upper gate layer 141. The sacrificial layer 180 may fill the first recess R1 and the second recess R2. In this case, the sacrificial layer 180 may be undoped polysilicon. According to embodiments, the sacrificial layer 180 may include oxide or silicon oxide. In this case, undoped polysilicon, oxide, or silicon oxide constituting the sacrificial layer 180 may be a material having a lower etch rate than polysilicon constituting the upper gate layer 141.

As shown in FIG. 6E, the depth D1 of the first recess R1 may be greater than the depth D2 of the second recess R2. Consequently, a proportion of the sacrificial layer 180 filling the first recess R1 on the first gate trench GT1 may be higher than a proportion of the sacrificial layer 180 filling the second recess R2 on the second gate trench GT2. Thereafter, as shown in FIG. 6F, the sacrificial layer 180 and a portion of the upper gate layer 141 may be etched to form the first and second upper gate lines 140a and 140b. As the width of the gate trenches GT1 and GT2 increases, the surface exposed in the etching process may be wider and the degree of etching of the upper gate layer 141 filling the gate trenches GT1 and GT2 per unit time may be higher. However, because the proportion of the sacrificial layer 180 filling the first recess R1 may be higher than the proportion of the sacrificial layer 180 filling the second recess R2, a time point at which the upper gate layer 170 filling the first gate trench GT1 is etched may be delayed. Therefore, even though the degree of etching of the upper gate layer 141 filling the first gate trench GT1 per unit time may be high, the vertical level of the upper surface of the first upper gate line 140a may be substantially equal to the vertical level of the upper surface of the second upper gate line 140b. FIG. 6F shows that the vertical level of the upper surface of the first upper gate line 140a may be substantially equal to the vertical level of the upper surface of the second upper gate line 140b, but according to embodiments, the upper surface of the first upper gate line 140a may be higher.

Also, according to a general etching process, the upper gate layer 141 may be etched so that the upper surfaces of the first and second upper gate lines 140a and 140b may have a downwardly concavely rounded profile. In the present embodiment, the first recess R1 may be deeper than the second recess R2 and may be in the upper gate layer 141 to increase the proportion of the sacrificial layer 180 filling the first recess R1 relative to the second recess R2. Consequently, compared to the second gate trench GT2, the degree of etching of the upper gate layer 141 buried in the first gate trench GT1 may be reduced. Accordingly, the first and second upper gate lines 140a and 140b may have a flat profile or an upwardly convex profile.

Referring to FIG. 6G, after filling the space remaining on the first and second upper gate lines 140a and 140b in the inner space of each of the gate trenches GT1 and GT2 with the first and second insulating capping layers 150a and 150b, unnecessary layers remaining on the substrate are removed to expose the upper surface of the substrate 110.

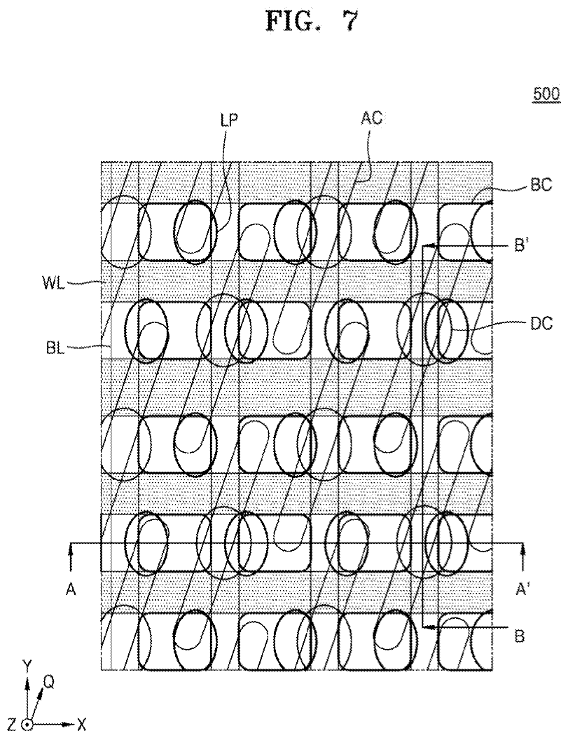

FIG. 7 is a schematic plan layout view of components of an IC device 500 according to example embodiments.

Referring to FIG. 7, a cell array region of the IC device 500 may include a plurality of active regions AC. A plurality of word lines WL may extend parallel to each other in the first horizontal direction (the X direction) across the active regions AC. A plurality of bit lines BL may extend parallel to each other in the second horizontal direction (the Y direction) on the word lines WL. The bit lines BL may be connected to the active regions AC through direct contacts DC.

A plurality of buried contacts BC may be between two adjacent bit lines BL among the bit lines BL. The buried contacts BC may be in a line in the first horizontal direction (the X direction) and the second horizontal direction (the Y direction). A plurality of landing pads LP may be on the buried contacts BC. The buried contacts BC and the landing pads LP may serve to connect a lower electrode of a capacitor on the bit lines BL to the active region AC. Each of the landing pads LP may partially overlap the buried contact BC.

FIGS. 8A to 8I are cross-sectional views of a method of manufacturing the IC device 500 according to example embodiments.

Referring to FIG. 8A, after forming the device isolation trenches TR in the cell array region of the substrate 110, the device isolation layers 112 filling the device isolation trenches TR may be formed. The active regions AC may be defined in the cell array region of the substrate 110 by the device isolation layers 112.

After forming the source/drain regions by implanting impurity ions into the upper surface of the active regions AC, the gate trenches GT1 and GT2 extending parallel to each other may be in the substrate 110. After cleaning a resultant structure of forming the gate trenches GT1 and GT2, the gate dielectric layers 120a and 120b, the lower gate lines 130a and 130b, the first and second upper gate lines 140a and 140b, and the first and second insulating capping layers 150a and 150b may be formed. The lower gate lines 130a and 130b may constitute the word lines WL illustrated in FIG. 7. In this example, a case in which some components of the IC device 100a illustrated in FIG. 2A may be in the gate trenches GT1 and GT2 is described as an example. In an implementation, in this example, components selected from among the IC devices 100b, 200, 300a, 300b, and 400 may be in the gate trenches GT1 and GT2.

Referring to FIG. 8B, an insulating layer 930 may be on the substrate 110. The insulating layer 930 may include a first insulating layer 932 and a second insulating layer 934 sequentially on the substrate 110. The first insulating layer 932 and the second insulating layer 934 may include different types of insulating materials. In an implementation, the first insulating layer 932 may include an oxide layer, and the second insulating layer 934 may include a nitride layer.

Referring to FIG. 8C, after a first conductive layer 950 may be on the substrate 110, a partial region of each of the first conductive layer 950, the second insulating layer 934, and the first insulating layer 932 and a partial region of the substrate 110 may be etched to form a plurality of direct contact holes DCH passing through the first conductive layer 950, the second insulating layer 934, and the first insulating layer 932 to expose the active region. Thereafter, the direct contacts DC filling the direct contact holes DCH may be formed.

The first conductive layer 950 may include doped polysilicon or a metal, such as W, Mo, Au, Cu, Al, Ni, or Co. The first conductive layer 950 may include a single layer including one material selected from the materials listed above or a multi-layer including at least two types of materials.

The direct contact DC may include doped polysilicon or a metal, such as W, Mo, Au, Cu, Al, Ni, or Co. In some embodiments, the direct contact DC may include the same material as that of the first conductive layer 950.

In some embodiments, a metal silicide layer may be between the substrate 110 and the direct contact DC. In an implementation, the metal silicide layer may include tungsten silicide, nickel silicide, or cobalt silicide.

Referring to FIG. 8D, a second conductive layer 952 and an insulating capping layer 956 are sequentially on the first conductive layer 950.

The second conductive layer 952 may include TiSiN, TiN, TaN, CoN, metal, or metal silicide. The metal and the metal silicide may include W, Mo, Au, Cu, Al, Ni, or Co. The insulating capping layer 956 may include a silicon nitride layer.

Referring to FIG. 8E, a mask pattern 970 may be on the insulating capping layer 956. A portion of an upper surface of the insulating capping layer 956 may be exposed through the mask pattern 970. The mask pattern 970 may include a silicon nitride layer.

Referring to FIG. 8F, a stack structure including the direct contact DC, the first conductive layer 950, the second conductive layer 952, and the insulating capping layer 956 may be etched using the mask pattern 970 as an etch mask to form a plurality of bit line structures BLS extending parallel to each other. The first conductive layer 950 and the second conductive layer 952 included in the bit line structures BLS may constitute the bit line BL illustrated in FIG. 7.

Referring to FIG. 8G, a plurality of insulating spacers 972 respectively covering both sidewalls of each of the bit line structures BLS may be formed, and a portion of the substrate 110 and a portion of the device isolation layer 112 exposed through the insulating spacers 972 may be etched to form a plurality of recesses RC exposing the active regions AC. Each of the recesses RC may communicate with the buried contact hole BCH having a width defined by a pair of insulating spacers 972 between two adjacent bit line structures BLS.

In order to form the insulating spacers 972 and the recesses RC, a process of forming a spacer insulating layer covering the bit line structures BLS and etching back the spacer insulating layer and a process of etching a portion of the substrate 110 and a portion of the device isolation layer 112 may be performed.

Referring to FIG. 8H, a buried conductive layer 982, a conductive barrier layer 986, and an upper conductive layer 988 may be sequentially stacked in the buried contact holes BCH, while filling the recesses RS between each of the bit line structures BLS. The buried conductive layer 982 may correspond to the buried contact BC shown in FIG. 7, and the conductive barrier layer 986 and the upper conductive layer 988 may correspond to the landing pad LP shown in FIG. 7. Also, portions of the upper conductive layers 988 extending on upper surfaces of the bit line structures BLS may be connected to lower electrodes of capacitors formed in a subsequent process. A metal silicide layer 984 may be located between the buried conductive layer 982 and the conductive barrier layer 986.

The buried conductive layers 982 may be formed by a chemical vapor deposition (CVD), a physical vapor deposition (PVD), or epitaxial growth process. The buried conductive layers 982 may include a semiconductor material doped with impurities, metal, a conductive metal nitride, or a metal silicide. The metal silicide layers 984 may include cobalt silicide, nickel silicide, or manganese silicide. In some embodiments, the metal silicide layer 984 may be omitted. The conductive barrier layers 986 may have a Ti/TiN stack structure. The upper conductive layers 988 may include doped polysilicon, metal, metal silicide, or a conductive metal nitride. In an implementation, the upper conductive layers 988 may include tungsten (W). The upper conductive layers 988 may be electrically insulated from each other by an insulating layer 990 filling a space therearound.

Referring to FIG. 8I, a capacitor structure 992 may be on the insulating layer 990. The capacitor structure 992 may include a plurality of capacitor lower electrodes 994 electrically connectable to the upper conductive layers 988. A capacitor upper electrode 995 may be on the capacitor lower electrodes 994, and a capacitor dielectric layer 993 may be located between the capacitor upper electrode 995 and the capacitor lower electrode 994.

By way of summation and review, IC devices having a high degree of integration used in electronic devices have been required, and design rules for components of IC devices have been reduced. Consequently, the difficulty of a manufacturing process for increasing an insulation effect between conductive patterns constituting IC devices has gradually increased. An integrated circuit (IC) device capable of enhancing an insulation effect between conductive patterns constituting the IC device is disclosed.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An integrated circuit (IC) device, comprising:
a substrate having a first gate trench and a second gate trench apart from the first gate trench in a horizontal direction;
a gate dielectric layer covering inner surfaces of the first gate trench and the second gate trench;
a first lower gate line filling a portion of the first gate trench on the gate dielectric layer;
a second lower gate line filling a portion of the second gate trench on the gate dielectric layer;
a first upper gate line on the first lower gate line in the first gate trench and having a first width in the horizontal direction; and
a second upper gate line on the second lower gate line in the second gate trench and having a second width smaller than the first width,
wherein a vertical level of an upper surface of the first upper gate line is higher than or substantially equal to a vertical level of an upper surface of the second upper gate line.

2. The IC device as claimed in claim 1, wherein a depth of the first gate trench in a vertical direction is greater than a depth of the second gate trench in the vertical direction.

3. The IC device as claimed in claim 1, wherein the upper surfaces of the first upper gate line and the second upper gate line are flat.

4. The IC device as claimed in claim 1, wherein:
the first upper gate line and the second upper gate line include doped polysilicon, and
the first lower gate line and the second lower gate line include Ti, TiN, Ta, TaN, W, WN, TiSiN, or WSiN.

5. The IC device as claimed in claim 1, wherein:
an uppermost end of a sidewall of the first upper gate line contacting the gate dielectric layer has a vertical level substantially equal to an uppermost surface of the first upper gate line, and
an uppermost end of a sidewall of the second upper gate line contacting the gate dielectric layer has a vertical level substantially equal to an uppermost surface of the second upper gate line.

6. The IC device as claimed in claim 1, wherein a vertical level of a lower surface of the first upper gate line is substantially equal to a vertical level of a lower surface of the second upper gate line.

7. The IC device as claimed in claim 1, further comprising:
a first insulating capping layer on the first upper gate line in the first gate trench; and
a second insulating capping layer on the second upper gate line in the second gate trench and having a width smaller than a width of the first insulating capping layer, wherein a vertical level of a lower surface of the first insulating capping layer is higher than or substantially equal to a vertical level of a lower surface of the second insulating capping layer.

8. The IC device as claimed in claim 7, wherein the lower surface of the first insulating capping layer and the lower surface of the second insulating capping layer are flat.

9. The IC device as claimed in claim 1, further comprising a first blocking layer covering at least a portion of an upper surface of the first upper gate line, wherein a lower surface of the first blocking layer is flat.

10. The IC device as claimed in claim 9, further comprising a second blocking layer covering at least a portion of an upper surface of the second upper gate line, wherein a vertical level of the lower surface of the second blocking layer is lower than or substantially equal to a vertical level of the lower surface of the first blocking layer, and the lower surface of the second blocking layer is flat.

11. An integrated circuit (IC) device, comprising:
a substrate having a first gate trench and a second gate trench apart from the first gate trench in a horizontal direction;
a gate dielectric layer covering inner surfaces of the first gate trench and the second gate trench;
a first lower gate line filling a portion of the first gate trench on the gate dielectric layer;
a second lower gate line filling a portion of the second gate trench on the gate dielectric layer;
a first upper gate line on the first lower gate line in the first gate trench; and
a second upper gate line on the second lower gate line in the second gate trench,
wherein a vertical level of an upper surface of the first upper gate line is higher than or substantially equal to a vertical level of an upper surface of the second upper gate line, and the upper surfaces of the first upper gate line and the second upper gate line have an upwardly convexly rounded profile.

12. The IC device as claimed in claim 11, wherein a first width of the first gate trench in the horizontal direction is greater than a second width of the second gate trench in the horizontal direction.

13. The IC device as claimed in claim 11, wherein:
an uppermost end of a sidewall of the first upper gate line contacting the gate dielectric layer has a vertical level lower than an uppermost surface of the first upper gate line, and
an uppermost end of a sidewall of the second upper gate line contacting the gate dielectric layer has a vertical level lower than an uppermost surface of the second upper gate line.

14. The IC device as claimed in claim 11, further comprising:
a first insulating capping layer on the first upper gate line; and
a second insulating capping layer on the second upper gate line,
wherein a vertical level of a lower surface of the first insulating capping layer is higher than or substantially equal to a vertical level of a lower surface of the second insulating capping layer.

15. The IC device as claimed in claim 14, wherein the lower surface of the first insulating capping layer and the lower surface of the second insulating capping layer have a downwardly concavely rounded profile.

16. The IC device as claimed in claim 11, further comprising a first blocking layer covering at least a portion of an upper surface of the first upper gate line, wherein a lower surface of the first blocking layer has a downwardly concavely rounded profile.

17. The IC device as claimed in claim 16, further comprising a second blocking layer covering at least a portion of the second upper gate line, wherein a vertical level of a lower surface of the second blocking layer is lower than or substantially equal to a vertical level of a lower surface of the first blocking layer, and the lower surface of the second blocking layer has a downwardly concavely rounded profile.

18. The IC device as claimed in claim 11, wherein the first upper gate line and the second upper gate line include a material different from a material of the first lower gate line and the second lower gate line.

19. An integrated circuit (IC) device, comprising:
a substrate including a first gate trench having a first width in a first horizontal direction and extending in a second horizontal direction orthogonal to the first horizontal direction and a second gate trench apart from the first gate trench in the first horizontal direction, having a depth deeper than a depth of the first gate trench in a vertical direction, and extending in the second horizontal direction;
a gate dielectric layer covering inner surfaces of the first gate trench and the second gate trench;
a first lower gate line filling a portion of the first gate trench on the gate dielectric layer;
a second lower gate line filling a portion of the second gate trench on the gate dielectric layer;
a first upper gate line on the first lower gate line in the first gate trench and having a first width in the horizontal direction; and
a second upper gate line on the second lower gate line in the second gate trench and having a second width greater than the first width,
wherein:
a vertical level of an upper surface and a vertical level of a lower surface of the first upper gate line are respectively higher than or substantially equal to a vertical level of an upper surface and a vertical level of a lower surface of the second upper gate line,
the first upper gate line and the second upper gate line include doped polysilicon,
the first lower gate line and the second lower gate line include Ti, TiN, Ta, TaN, W, WN, TiSiN, or WSiN, and
upper surfaces of the first upper gate line and the second upper gate line have an upwardly convexly rounded profile.

20. The IC device as claimed in claim 1, further comprising:
a first insulating capping layer on the first upper gate line;
a second insulating capping layer on the second upper gate line;
a first blocking layer located between the first insulating capping layer and the first upper gate line; and
a second blocking layer located between the second insulating capping layer and the second upper gate line,
wherein:
a vertical level of a lower surface of the first insulating capping layer is higher than or substantially equal to a vertical level of a lower surface of the second insulating capping layer,
the lower surface of the first insulating capping layer, the lower surface of the second insulating capping layer, a lower surface of the first blocking layer, and a lower surface of the second blocking layer have a downwardly concavely rounded profile, and
a vertical level of the lower surface of the first blocking layer is higher than or substantially equal to a vertical level of the lower surface of the second blocking layer.
